(19) United States
(12) Patent Application Publication
(10) Pub. No.: US 2025/0337414 A1
(43) Pub. Date: Oct. 30, 2025

(54) CONFIGURABLE LOGIC SLICES FOR PROGRAMMABLE LOGIC DEVICES

(71) Applicant: Lattice Semiconductor Corporation, Hillsboro, OR (US)

(72) Inventor: Bradley A. Sharpe-Geisler, San Jose, CA (US)

(21) Appl. No.: 19/191,964

(22) Filed: Apr. 28, 2025

Related U.S. Application Data
(60) Provisional application No. 63/640,123, filed on Apr. 29, 2024.

(51) Int. Cl. H03K 19/17728; H03K 19/17748

(52) U.S. Cl. CPC H03K 19/17728; H03K 19/17748

(57) ABSTRACT

Configurable logic slices for programmable logic devices and methods of using and programming such logic slices and devices are presented herein. In one embodiment, a programmable logic device (PLD) is disclosed that includes a logic slice. The logic slice may include a first look-up table (LUT) configured to generate a first output; and an input switch stage configured to receive the first output and selectively generate a first signal. The logic slice may further include a second LUT configured to receive the first signal and to generate a second output; and a two-to-one multiplexer configured to receive the first output and the second output and selectively produce an output of the logic slice.

### CROSS-REFERENCE TO RELATED APPLICATION

This patent application claims the benefit of and priority to U.S. Provisional Patent Application No. 63/640,123 filed Apr. 29, 2024 and entitled “CONFIGURABLE LOGIC SLICES FOR PROGRAMMABLE LOGIC DEVICES,” which is incorporated herein by reference in its entirety.

### TECHNICAL FIELD

The present disclosure relates generally to programmable logic devices (PLDs) and, more particularly, to PLDs having improved logic slice configurations.

### BACKGROUND

Programmable logic devices (PLDs) (e.g., field programmable gate arrays (FPGAs), complex programmable logic devices (CPLDs), field programmable systems on a chip (FPSCs), or other types of programmable devices) may be configured with various user designs to implement desired functionality. Typically, user designs are synthesized and mapped into configurable resources (e.g., programmable logic gates, look-up tables (LUTs), embedded hardware, or other types of resources) and interconnections available in particular PLDs. Physical placement and routing for the synthesized and mapped user designs may then be determined to generate configuration data for the particular PLDs.

A PLD may include a number of programmable logic blocks (PLBs) and configurable routing resources that may be used to interconnect the PLBs. Logic block design involves complex tradeoffs among various quantities, such as area, speed, cost, and functionality. For example, there is a desire to implement functionality approaching that of complex LUT structures in PLBs but using a fraction of the hardware and with lower power consumption. Thus, there is a need for PLBs that provide increasing levels of functionality but at a fraction of the area or power consumption.

### SUMMARY

Embodiments of the present disclosure include configurable logic slices for programmable logic devices and methods of using and programming such logic slices and devices.

In an exemplary aspect, a PLD is disclosed. In some embodiments, the PLD includes a logic slice. The logic slice may include a first LUT configured to generate a first output; and an input switch stage configured to receive the first output and selectively generate a first signal. The logic slice may further include a second LUT configured to receive the first signal and to generate a second output; and a two-to-one multiplexer configured to receive the first output and the second output and selectively produce an output of the logic slice.

In another exemplary aspect, a method of operating a PLD that includes a logic slice is disclosed. The method may include operating the logic slice. Operating the logic slice may include generating, by a first LUT, a first output; receiving, by an input switch stage, the first output; and selectively generating, by the input switch stage, a first signal. The method may further include receiving, by a second LUT, the first signal; generating, by the second LUT, a second output; and selectively producing, by a two-to-one multiplexer, an output of the logic slice from the first output and the second output.

In another exemplary aspect, a method of programming a PLD is disclosed. The PLD that is programmed may include a plurality of logic slices. Each of the plurality of logic slices may include a first lookup table (LUT) configured to generate a first output; an input switch stage configured to receive the first output and selectively generate a first signal; a second LUT configured to receive the first signal and to generate a second output; and a two-to-one multiplexer configured to receive the first output and the second output and selectively produce an output of the logic slice. The method of programming the PLD having logic slices may include generating configuration data to configure physical components of the PLD in accordance with a synthesized design comprising, for each logic slice, an operating mode depending on the configuration of the input switch stage; and programming the PLD with the configuration data.

Additional aspects, features, and advantages of the present disclosure will become apparent from the following detailed description.

### BRIEF DESCRIPTION OF THE DRAWINGS

The accompanying drawing figures incorporated in and forming a part of this specification illustrate several aspects of the disclosure, and together with the description, serve to explain the principles of the disclosure.

FIG. 1 illustrates a block diagram of a programmable logic device (PLD) in accordance with some aspects of the present disclosure.

FIG. 2A Illustrates a block diagram of a logic block of a PLD in accordance with some aspects of the present disclosure.

FIG. 2B illustrates a logic block, according to some aspects of the present disclosure.

FIG. 3 illustrates an example logic slice 300, according to some aspects of the present disclosure.

FIG. 4 illustrates an example detailed four-input LUT (4LUT) structure, according to some aspects of the present disclosure.

FIGS. 5A-5F illustrate different configurations of a logic slice, according to some aspects of the present disclosure.

FIG. 6 illustrates an example configuration of a logic slice, according to some aspects of the present disclosure.

FIG. 7 illustrates an example logic slice block, according to some aspects of the disclosure.

FIGS. 8A-8C illustrate different configurations of a logic slice block, according to some aspects of the present disclosure.

FIG. 9 illustrates another example logic slice block, according to some aspects of the disclosure.

FIGS. 10A-10E illustrate different configurations of a logic slice block, according to some aspects of the present disclosure.

FIG. 11 is an example method of operating a logic slice, according to some aspects of the disclosure.

FIG. 12 illustrates a design process for a PLD, in accordance with some aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

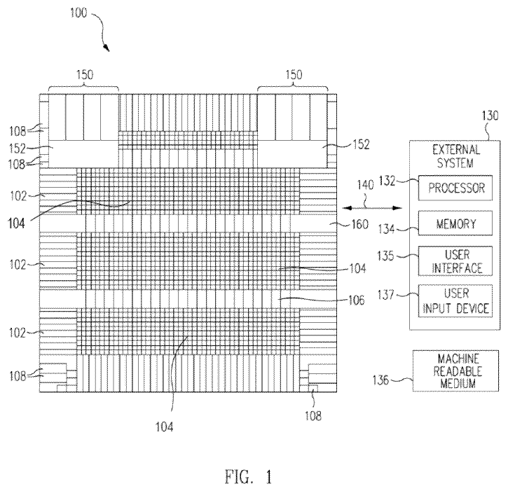

FIG. 1 illustrates a block diagram of a programmable logic device (PLD) 100 in accordance with some aspects of the present disclosure. The PLD 100 may be an FPGA, a CPLD, an FPSC, or other type of programmable device. The PLD 100 generally includes input/output (I/O) blocks 102 and logic blocks 104 (e.g., also referred to as programmable logic blocks (PLBs), programmable functional units (PFUs), or programmable logic cells (PLCs)).

I/O blocks 102 provide I/O functionality (e.g., to support one or more I/O and/or memory interface standards) for PLD 100, while logic blocks 104 provide logic functionality (e.g., LUT-based logic or logic gate array-based logic) for PLD 100. Additional I/O functionality may be provided by serializer/deserializer (SERDES) blocks 150 and physical coding sublayer (PCS) blocks 152. PLD 100 may also include hard intellectual property core (IP) blocks 160 to provide additional functionality (e.g., substantially predetermined functionality provided in hardware which may be configured with less programming than logic blocks 104).

PLD 100 may also include blocks of memory 106 (e.g., blocks of EEPROM, block SRAM, and/or flash memory), clock-related circuitry 108 (e.g., clock sources, PLL circuits, and/or DLL circuits), and/or various routing resources (e.g., interconnect and appropriate switching logic to provide paths for routing signals throughout PLD 100, such as for clock signals, data signals, or others) as appropriate. In general, the various elements of PLD 100 may be used to perform their intended functions for desired applications, as would be understood by one skilled in the art.

For example, certain I/O blocks 102 may be used for programming memory 106 or transferring information (e.g., various types of user data and/or control signals) to/from PLD 100. Other I/O blocks 102 include a first programming port (which may represent a central processing unit (CPU) port, a peripheral data port, an SPI interface, and/or a sysCONFIG programming port) and/or a second programming port such as a joint test action group (JTAG) port (e.g., by employing standards such as Institute of Electrical and Electronics Engineers (IEEE) 1149.1 or 1532 standards). In various embodiments, I/O blocks 102 may be included to receive configuration data and commands (e.g., over one or more connections 140) to configure PLD 100 for its intended use and to support serial or parallel device configuration and information transfer with SERDES blocks 150, PCS blocks 152, hard IP blocks 160, and/or logic blocks 104 as appropriate.

It should be understood that the number and placement of the various elements are not limiting and may depend upon the desired application. For example, various elements may not be required for a desired application or design specification (e.g., for the type of programmable device selected).

Furthermore, it should be understood that the elements are illustrated in block form for clarity and that various elements would typically be distributed throughout PLD 100, such as in and between logic blocks 104, hard IP blocks 160, and routing resources to perform their conventional functions (e.g., storing configuration data that configures PLD 100 or providing interconnect structure within PLD 100). It should also be understood that the various embodiments disclosed herein are not limited to programmable logic devices, such as PLD 100, and may be applied to various other types of programmable devices, as would be understood by one skilled in the art.

An external system 130 may be used to create a desired user configuration or design of PLD 100 and generate corresponding configuration data to program (e.g., configure) PLD 100. For example, system 130 may provide such configuration data to one or more I/O blocks 102, SERDES blocks 150, and/or other portions of PLD 100. As a result, logic blocks 104, various routing resources, and any other appropriate components of PLD 100 may be configured to operate in accordance with user-specified applications.

In the illustrated embodiment, system 130 is implemented as a computer system. In this regard, system 130 includes, for example, one or more processors 132 which may be configured to execute instructions, such as software instructions, provided in one or more memories 134 and/or stored in non-transitory form in one or more non-transitory machine readable mediums 136 (e.g., which may be internal or external to system 130). For example, in some embodiments, system 130 may run PLD configuration software, such as Lattice Diamond System Planner software available from Lattice Semiconductor Corporation to permit a user to create a desired configuration and generate corresponding configuration data to program PLD 100.

System 130 also includes, for example, a user interface 135 (e.g., a screen or display) to display information to a user, and one or more user input devices 137 (e.g., a keyboard, mouse, trackball, touchscreen, and/or other device) to receive user commands or design entry to prepare a desired configuration of PLD 100.

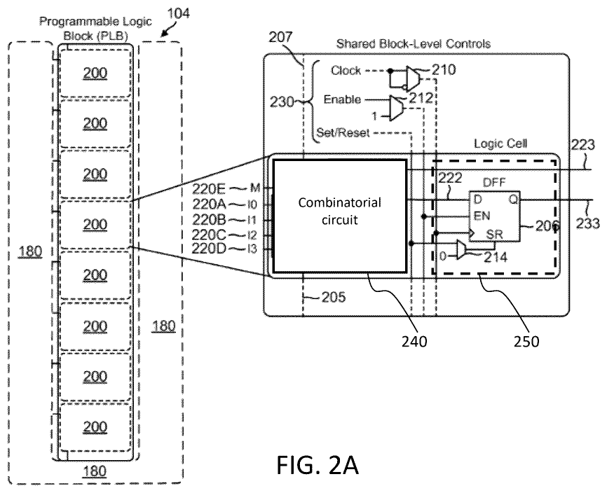

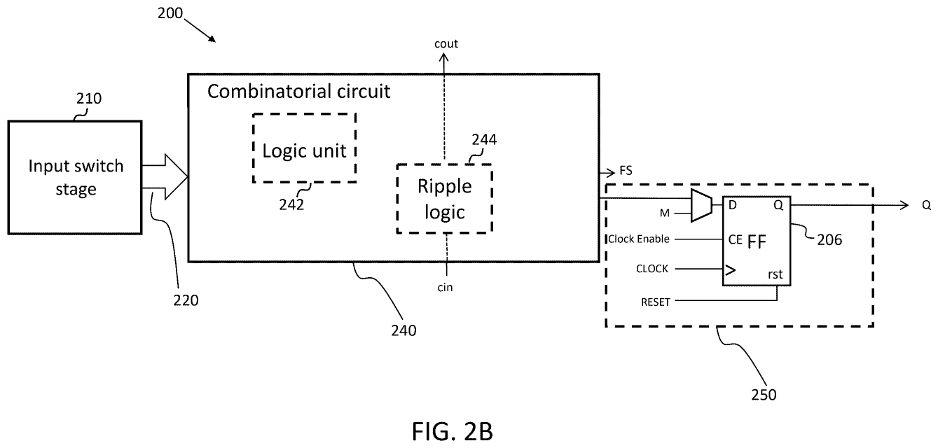

FIG. 2A illustrates a block diagram of a logic block 104 of PLD 100 in accordance with some aspects of the present disclosure. As discussed, PLD 100 includes a plurality of logic blocks 104 including various components to provide logic and arithmetic functionality.

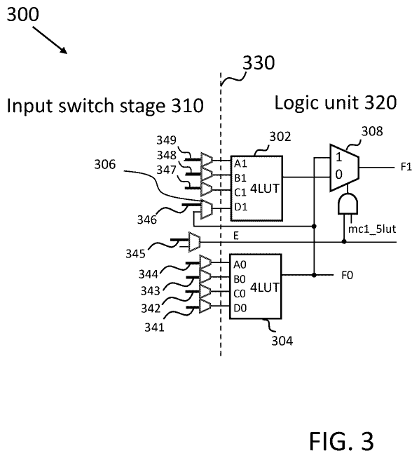

In the example embodiment shown in FIG. 2, logic block 104 may be interconnected to other logic blocks using routing resources 180. Each logic block 104 includes a combinatorial circuit 240 and a register circuit 250. In more detail, each logic block 104 may include various components such as: one or more lookup tables (LUTs), mode logic circuitry, a register 206 (e.g., a flip-flop or latch), and various programmable multiplexers (e.g., programmable multiplexers 212 and 214) for selecting desired signal paths for logic block 104 and/or between logic blocks 104. In this example, combinatorial circuit 240 accepts four inputs 220A-220D. The combinatorial circuit 240 may implement or include a four-input LUT (which may be abbreviated as “4LUT” or “LUT4”) that can be programmed by configuration data for PLD 100 to implement any appropriate logic operation having four inputs or less. Combinatorial circuit 240 may include various logic elements and/or additional inputs, such as input 220E, to support the functionality of the various modes or to support logic configurations with a greater number of inputs, as described herein (e.g., with respect to FIG. 3, 6, 7, or 9). A LUT within combinatorial circuit 240 may be of any other suitable size having any other suitable number of inputs for a particular implementation of a PLD. In some embodiments, different size LUTs may be provided for different logic blocks 104.

An output signal 222 from combinatorial circuit 240 may in some embodiments be passed through register 206 to provide an output signal 233 of logic block 104. In various embodiments, an output signal 223 from combinatorial circuit 240 may be passed to output 223 directly, as shown. Depending on the configuration of multiplexers 210-214 and/or mode logic within the combinatorial circuit 240, output signal 222 may be temporarily stored (e.g., latched) in register 206 according to control signals 230. In some embodiments, configuration data for PLD 100 may configure output 223 and/or 233 of logic block 104 to be provided as one or more inputs of another logic block 104 (e.g., in another logic block or the same logic block) in a staged or cascaded arrangement (e.g., comprising multiple levels) to configure logic operations that cannot be implemented in a single logic block 104 (e.g., logic operations that have too many inputs to be implemented by a single LUT). Moreover, logic block 104 may be implemented with multiple outputs and/or interconnections to facilitate selectable modes of operation, as described herein.

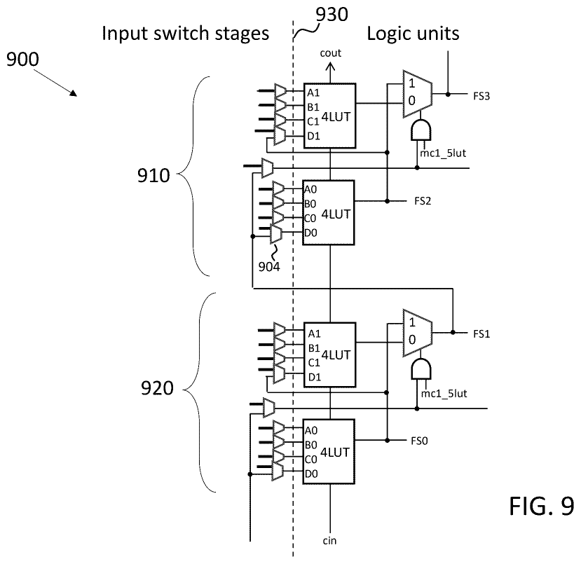

The combinatorial circuit 240 may include mode logic circuitry that may be utilized for some configurations of PLD 100 to efficiently implement arithmetic operations such as adders, subtractors, comparators, counters, or other operations, to efficiently form some extended logic operations (e.g., higher order LUTs, working on multiple bit data), to efficiently implement a relatively small RAM, and/or to allow for selection between logic, arithmetic, extended logic, and/or other selectable modes of operation. In this regard, logic circuits across multiple logic blocks 104, may be chained together to pass carry-in signals 205 and carry-out signals 207, and/or other signals (e.g., output signals 222) between adjacent logic blocks 104, as described herein. In some embodiments, logic circuits within combinatorial circuit 240 may be chained across multiple logic blocks 104. More detailed embodiments are provided in FIGS. 9-12.

Logic block 104 illustrated in FIG. 2 is merely an example, and logic blocks 104 according to different embodiments may include different combinations and arrangements of PLD components. Each of the logic blocks 104 may be used to implement a portion of a user design implemented by PLD 100. In this regard, PLD 100 may include many logic blocks 104, which are used to collectively implement the user design.

FIG. 2B illustrates a logic block 200, such as logic block 104, according to some aspects of the present disclosure. The logic block 200 includes a combinatorial part or circuit 240 coupled to a register part or circuit 250 as shown. The logic block 200 further includes an input switch stage 210 that provides inputs 220 to combinatorial circuit 240. The input switch stage 210 may be part of routing resources, such as routing resources 180, or may be considered as part of the combinatorial circuit 240. The combinatorial circuit 240 includes at least one logic unit 242 and ripple logic 244. The ripple logic 244 is configured to perform a variety of arithmetic or ripple functions (such as add, subtract, multiply, increment), along with a carry to a next bit. The register circuit 250, that includes register 206 (e.g., a flip-flop or latch), supports sequential functions. A logic unit 242 is provided for performing general logic. Further detail on exemplary input switch stages 210 and logic units 242 are provided below.

Hereafter, it is assumed that a typical logic block 200 in a PLD includes an input switch stage, a combinatorial part, a register part and that the combinatorial part includes both ripple logic and logic block slices (e.g., as exemplified in FIG. 2B). Thus, many, if not all, logic blocks in a PLD have a structure as exemplified in FIG. 2B. The main focus of the remainder of this disclosure is on input switch stage and logic unit structure and operation, so the register circuit 250 and ripple logic 244 are not illustrated in the remaining figures. In some embodiments, an input switch stage and logic unit together form a logic slice. It is also assumed that distributed RAM may also be supported, but that functionality is known and not made explicit in the figures.

FIG. 3 illustrates an example logic slice 300, according to some aspects of the present disclosure. The logic slice 300 in this embodiment includes an input switch stage 310 and logic unit 320, which are functionally divided by line 330 as shown. The logic unit 320 includes a first four-input LUT (or 4LUT) 302 and a second 4LUT 304. The output F0 of 4LUT 304 is fed back to the input switch stage 310 and switchably provided to input D1 of 4LUT 302. In an embodiment, the input D1 represents the fastest input of 4LUT 302.

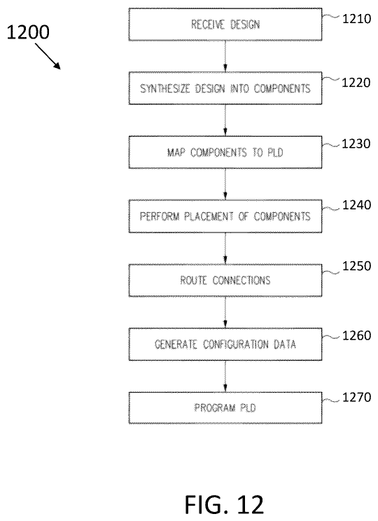

In an embodiment, the input switch stage 310 includes a number of multiplexers (e.g., n-to-one or n:1 multiplexers) that receive a number (e.g., n) input signals. In the embodiment in FIG. 3, the input stage includes nine multiplexers, such as multiplexer 306. Each of the nine input lines 341-349 represent a bus with multiple signals (e.g., two, three, four, or more signals). Configuration bits (not shown) may be used as inputs to each of the multiplexers (e.g., multiplexer 306) in the input switch stage 310 to select a particular signal line. Configuration bits may be enabled or disabled (e.g., via stored logic values) during the design process, such as presented in FIG. 12. For example, configuration data generated during the design process may establish the configuration bits that select the appropriate signal lines.

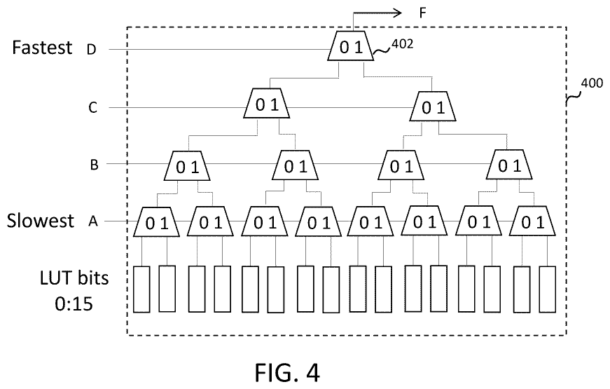

FIG. 4 illustrates an example detailed 4LUT structure 400, according to some aspects of the present disclosure. The 4LUT structure 400 includes a configuration of two-to-one (also abbreviated as 2:1) multiplexers, one of which is labeled as 402, connected to input bits A-D, with the slowest input illustrated as A and the fastest input illustrated as D. In an embodiment, inputs A-D correspond to inputs A1-D1 in 4LUT 302, such that D1 is the fastest input.

Returning to FIG. 3, the output F0 of 4LUT 304 is also provided as one of two inputs to two-to-one multiplexer 308. An input, labeled E in FIG. 3, is used to select the output of multiplexer 308, when configuration bit mc1_5lut is enabled (via use of the illustrated AND gate logic). Configuration bits may be enabled or disabled (e.g., via stored logic values) during the design process, such as presented in FIG. 12.

The logic slice 300 provides flexibility in logic configurations or modes. For example, a logic slice 300 can be configured either as two independent 4LUTs (having independent inputs for the 4LUTs 302, 304 or as a 5LUT with the 4LUTs having shared inputs (and using the 2:1 multiplexer 308 to dynamically select between the two 4-LUTs 302, 304) or as a so-called S44 LUT structure. An S44 LUT structure connects the output from one 4LUT (e.g. 304) into an input of the second LUT (e.g., 302). In this case, the first 4LUT 304 output F0 is connected to the second 4LUT 302 using a dedicated fast connection to the fastest input (D1) of the downstream 4LUT, such F0 is received by the fastest input D1. As shown in FIG. 4, not all 4-LUT inputs have equal delay, so by connecting to the fastest input with special hardware the performance be comparable to a 5LUT mode.

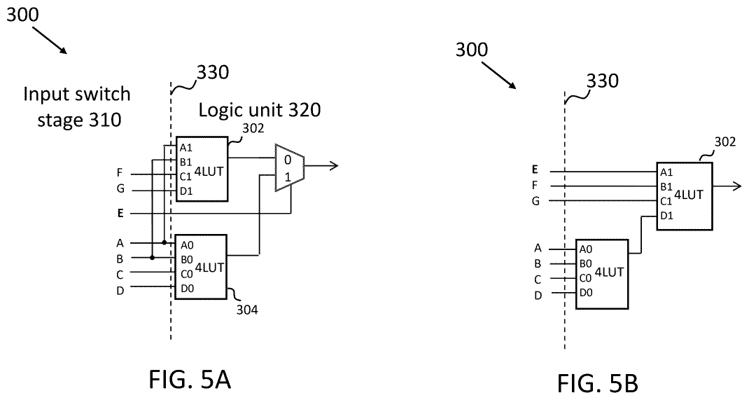

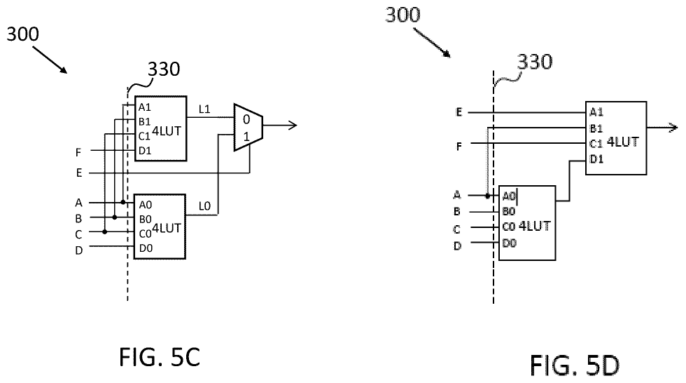

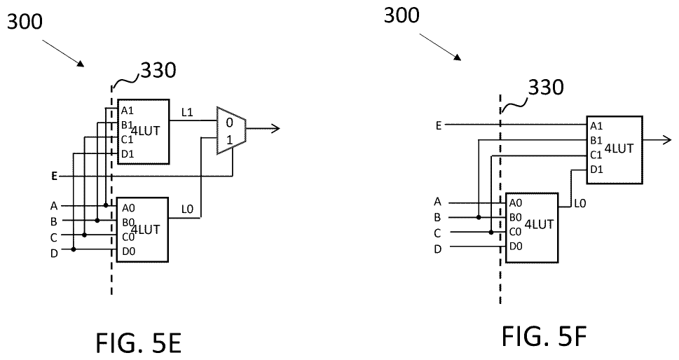

FIGS. 5A-5F illustrate different configurations or modes of logic slice 300, according to some aspects of the present disclosure. The different configurations of logic slice 300 may depend on the configuration of the input switch stage 310 that provides routing of input signals and the signal selection made in the 2:1 multiplexer 308. FIGS. 5A-5F illustrate different input switch stage 310 configurations and therefore configurations of logic slice 300. The multiplexers in input switch stage 310 are not illustrated; instead, what is illustrated are the signal connections provided as a result of multiplexer configurations (such as multiplexer 306 in input switch stage 310).

FIG. 5A illustrates logic slice 300 configured to receive seven independent inputs A through F. The inputs A1 and B1 to 4LUT 302 are the same as inputs A0 and B0 to 4LUT 304. A 2:1 multiplexer that drives the output is controlled by the E input to select between the two 4LUTs 302 and 304. FIG. 5B illustrates logic slice 300 also configured to receive seven independent inputs A-F. In FIG. 5B, logic slice 300 is configured in a so-called S44 configuration or S44 LUT structure using a dedicated fast connection to the fastest input of the downstream 4LUT 302. In FIG. 5B, the multiplexer 306 (shown in FIG. 3) is configured in the input state to select the output of 4LUT 304 as the input to D1.

FIG. 5C is similar to 5A except that logic slice 300 is configured with six independent inputs A through F, with A1-C1 set equal to A0-C0. In FIG. 5D is an S44-type LUT structure with six independent inputs A through F. FIG. 5E is similar to 5A and 5C except that logic slice 300 is configured with 5 independent inputs A through E, with A1-D1 set equal to A0-D0. In FIG. 5F, logic slice 300 is configured as an S44-type LUT structure with 5 independent inputs A-E. The configurations in FIGS. 5A-5F demonstrate the configurability of logic slice 300. Logic slice 300 can be configured to achieve all 5-input and a large percentage of commonly used 6-input and 7-input functions.

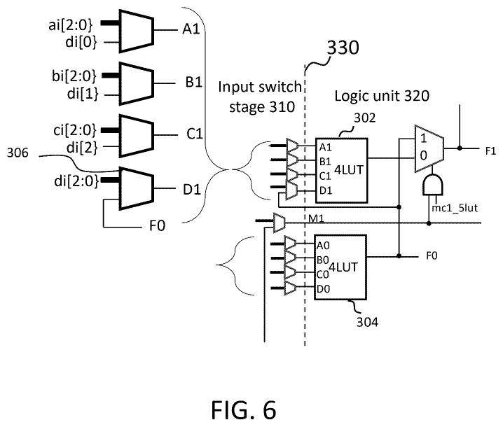

FIG. 6 illustrates an example configuration of logic slice 300, according to some aspects of the present disclosure. In the configuration in FIG. 6, additional inputs added to multiplexers of LUT ports A1, B1, C1 (within input switch stage 310) of the downstream LUT 302 to enhance connect-ability in S44LUT structure mode. No additional inputs are needed for the inputs for LUT 304. An option is provided to provide di[2:0] to inputs A1-C1 because these inputs may be blocked at multiplexer 306 by F0 at the D1 input. The inputs di[2:0] can be multiplexed into other inputs.

One property of a LUT is its capability for Boolean port swapping. As LUTs may be logically symmetrical, the input ports can be arranged in any order (by adjusting Boolean equations to realize the intended functionality). In an S44 LUT structure, the D-input of the downstream LUT is taken and not available for swapping. Consequently, the other input choices of the ISB for the D input may be cut off. This can be ameliorated by richening the input choices of inputs A, B and C. This way, the routing choices which had been spread across A, B, C, and D are now spread across A, B, and C, where D still has its original choices as well as the high-speed connection from the upstream LUT (for S44 LUT structure mode).

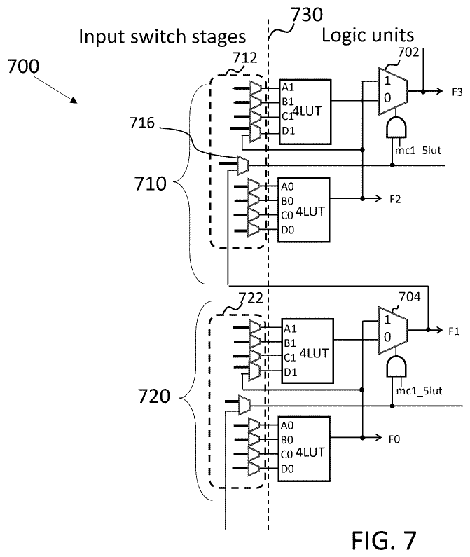

FIG. 7 illustrates an example logic slice block 700, according to some aspects of the disclosure. The logic slice block 700 includes two logic slices 710 and 720 interconnected as shown. The structure of logic slices 710 and 720 is identical to the structure of logic slice 300 described previously. The output F1 of first logic slice 720 is connected to the input switch stage 712 of second logic slice 710. The input switch stages 712, 722 of each logic slice 710, 720, respectively, are functionally separated from the logic units of each logic slice 710, 720 by line 730. The logic slice 720 may be referred to as the first logic slice of logic slice block 700, and the logic slice 710 may be referred to as the second logic slice of logic slice block 700. The output F1 of first logic slice 720 is provided to the multiplexer 716 of second input stage 712, with the output of multiplexer 716 providing a control of multiplexer 702. Two slices 710, 720 can be configured to implement various structures, depending on the configurations of the input switch stages and signal selection by multiplexers 702 and 704.

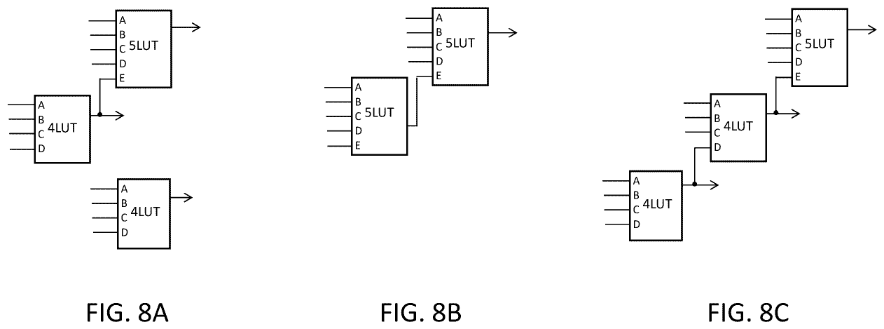

FIGS. 8A-8C illustrate different configurations of logic slice block 700, according to some aspects of the present disclosure. The configurations labeled “5LUT” represent two 4LUTs, such as those in logic slice 720, connected to a two-to-one multiplexer, such as multiplexer 704, to implement 5LUT functionality. The configuration in FIG. 8A may be referred to as S45 plus a 4LUT configuration (or mode); the configuration in FIG. 8B may be referred to as an S55 configuration (or mode); and the configuration in FIG. 8C may be referred to as an S445 configuration (or mode). The two slices 710, 720 may be connected to implement any of these configurations. The choice of which of these modes depends in part on the configuration of the upstream slice 720. The multiplexers in input switch stages 712, 722 are not illustrated in FIGS. 8A-8C; instead, what is illustrated are the signal connections provided as a result of multiplexer configurations (such as multiplexer 716 in input switch stage 712).

If the upstream slice 720 is configured as a 5-LUT the resulting structure can be an S55 LUT structure that can implement many commonly used 9-input functions along with some functions up to 17 inputs. If the upstream slice 720 is configured as an S44 LUT structure, the two slices 710, 720 together provide an S445 LUT structure that can implement logic functions that are distinct from those implemented in the S55 LUT structure that range from 9 to 15 inputs. If the upstream slice 720 is configured as two independent 4LUTs, the two slices 710, 720 may combine to form an S45 LUT structure plus an independent 4LUT. The S45 LUT structure may implement most 7 and 8 input functions plus some up to 12 inputs.

FIG. 9 illustrates another example logic slice block 900, according to some aspects of the disclosure. The logic slice block 900 includes two logic slices 910 and 920 interconnected as shown. The structure of logic slices 910 and 920 is identical to the structure of logic slice 300 described previously. The interconnection of logic slices 910, 920 is different than the interconnection of logic slices 710, 720 by virtue of the added high-speed connection from the upstream slice 920 to the input stage (multiplexer 904 in this embodiment) of the upstream 4LUT in slice 910. This added connection adds capability compared to the logic slice block 700.

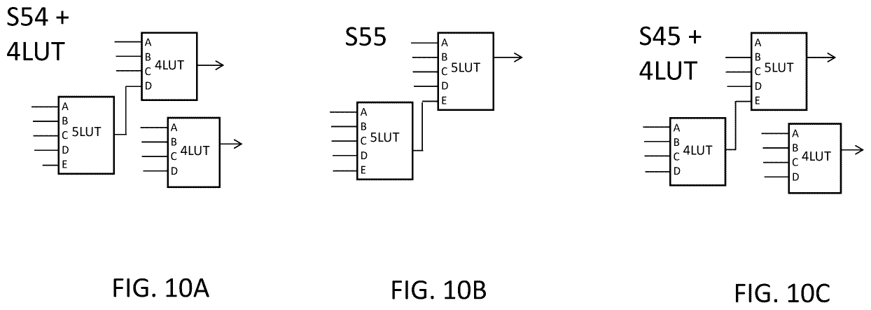

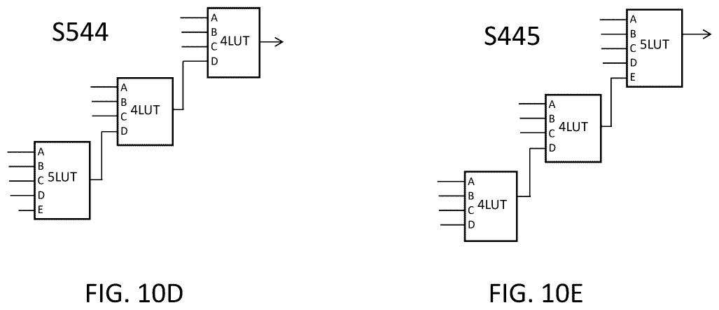

FIGS. 10A-10E illustrate different configurations of logic slice block 900, according to some aspects of the present disclosure. The two slices 910, 920 can be connected to implement either an S55 LUT structure (FIG. 10B), or an S45 LUT structure (with an independent 4-LUT) (FIG. 10C), or an S445 LUT structure (FIG. 10E), or an S54 LUT structure (with an independent 4-LUT) (FIG. 10A), or an S544 LUT structure (FIG. 10D).

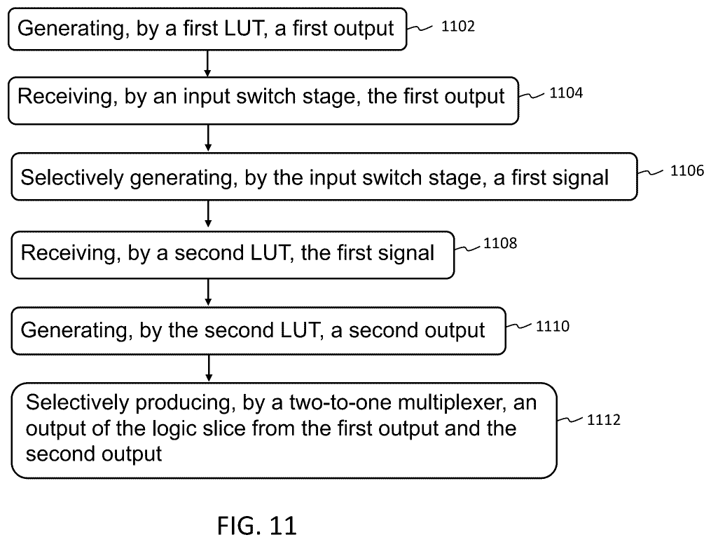

FIG. 11 is an example method of operating a logic slice, such as logic slices 300, 710, 720, 910, or 920, according to some aspects of the disclosure. The logic slice may include an input switch stage and a logic unit, such as input switch stage 310 and logic unit 320. The logic unit may include a first LUT and a second LUT whose outputs are connected to a multiplexer, such as 4LUTs 302, 304 and multiplexer 308. In step 1102, a first LUT generates a first output, such as the 4LUT 304 and output F0 in FIG. 3. In step 1104, an input switch stage receives the first output, such as the input switch stage 310 receiving F0. In step 1106, the input switch stage selectively generates a first signal. For example, the multiplexer 306 receives signals on bus 346 and F0 and selects one of these input signals to output as a first signal (e.g., selection based on configuration bits settings). In step 1108, a second LUT receives the first signal. For example, the 4LUT 302 receives an output of multiplexer 306. In step 1110, the second LUT generates a second output. For example, the 4LUT 302 generates an output as shown in FIG. 3. In step 1112, a two-to-one multiplexer selectively produces or generates an output of the logic slice from the first output and the second output. For example, multiplexer 308 receives an output F0 from 4LUT 304 and an output from 4LUT 302 and selects one of those output as the output labeled F1 in FIG. 3. In an embodiment, the selected output is based on an input E and a configuration bit setting mc1_5lut, as shown in FIG. 3.

FIG. 12 illustrates a design process 1200 for a PLD, according to some aspects of the present disclosure. For example, the process of FIG. 12 may be performed by system 130 running Lattice Diamond software to configure PLD 100. In some embodiments, the various files and information referenced in FIG. 12 may be stored, for example, in one or more databases and/or other data structures in memory 134, machine readable medium 136, and/or otherwise.

In operation 1210, system 130 receives a user design that specifies the desired functionality of PLD 100. For example, the user may interact with system 130 (e.g., through user input device 137 and hardware description language (HDL) code representing the design) to identify various features of the user design (e.g., high level logic operations, hardware configurations, and/or other features). In some embodiments, the user design may be provided in a register transfer level (RTL) description (e.g., a gate level description). System 130 may perform one or more rule checks to confirm that the user design describes a valid configuration of PLD 100. For example, system 130 may reject invalid configurations and/or request the user to provide new design information as appropriate.

In operation 1220, system 130 synthesizes the design to create a netlist (e.g., a synthesized RTL description) identifying an abstract logic implementation of the user design as a plurality of logic components (e.g., also referred to as netlist components). In some embodiments, the netlist may be stored in Electronic Design Interchange Format (EDIF) in a Native Generic Database (NGD) file.

In some embodiments, synthesizing the design into a netlist in operation 1220 may involve converting (e.g., translating) the high-level description of logic operations, hardware configurations, and/or other features in the user design into a set of PLD components (e.g., logic blocks 104, 200, logic slices 300, logic slice blocks, etc. and other components of PLD 100 configured for logic, arithmetic, or other hardware functions to implement the user design) and their associated interconnections or signals. Depending on embodiments, the converted user design may be represented as a netlist.

In some embodiments, synthesizing the design into a netlist in operation 1220 may further involve performing an optimization process on the user design (e.g., the user design converted/translated into a set of PLD components and their associated interconnections or signals) to reduce propagation delays, consumption of PLD resources and routing resources, and/or otherwise optimize the performance of the PLD when configured to implement the user design. Depending on embodiments, the optimization process may be performed on a netlist representing the converted/translated user design. Depending on embodiments, the optimization process may represent the optimized user design in a netlist (e.g., to produce an optimized netlist).

In some embodiments, the optimization process may include optimizing certain instances of a logic function operation, a ripple arithmetic operation, and/or an extended logic function operation which, when a PLD is configured to implement the user design, would occupy a plurality of configurable PLD components (e.g., logic blocks 104 and/or routing resources 180). For example, the optimization process may include detecting multiple mode or configurable logic blocks implementing logic function operations, ripple arithmetic operations, extended logic function operations, and/or corresponding routing resources in the user design, interchanging operational modes of logic blocks implementing the various operations to reduce the number of PLD components and/or routing resources used to implement the operations and/or to reduce the propagation delay associated with the operations, and/or reprogramming corresponding LUTs and/or mode logic to account for the interchanged operational modes.

In another example, the optimization process may include detecting extended logic function operations and/or corresponding routing resources in the user design, implementing the extended logic operations into multiple mode or convertible logic blocks with single physical logic block outputs, routing or coupling the logic block outputs of a first set of logic blocks to the inputs of a second set of logic blocks to reduce the number of PLD components used to implement the extended logic operations and/or routing resources and/or to reduce the propagation delay associated with the extended logic operations, and/or programming corresponding LUTs and/or mode logic to implement the extended logic function operations with at least the first and second sets of logic blocks.

In another example, the optimization process may include detecting multiple mode or configurable logic blocks implementing logic function operations, ripple arithmetic operations, extended logic function operations, and/or corresponding routing resources in the user design, interchanging operational modes of logic blocks implementing the various operations to provide a programmable register along a signal path within the PLD to reduce propagation delay associated with the signal path, and reprogramming corresponding LUTs, mode logic, and/or other logic block control bits/registers to account for the interchanged operational modes and/or to program the programmable register to store or latch a signal on the signal path.

In operation 1230, system 130 performs a mapping process that identifies components of PLD 100 that may be used to implement the user design. In this regard, system 130 may map the optimized netlist (e.g., stored in operation 1220 as a result of the optimization process) to various types of components provided by PLD 100 (e.g., logic blocks 104 or 200, logic slices 300, or logic slice blocks 700 or 900, embedded hardware, and/or other portions of PLD 100) and their associated signals (e.g., in a logical fashion, but without yet specifying placement or routing). In some embodiments, the mapping may be performed on one or more previously-stored NGD files, with the mapping results stored as a physical design file (e.g., also referred to as an NCD file). In some embodiments, the mapping process may be performed as part of the synthesis process in operation 1220 to produce a netlist that is mapped to PLD components.

In operation 1240, system 130 performs a placement process to assign the mapped netlist components to particular physical components residing at specific physical locations of the PLD 100 (e.g., assigned to particular logic blocks 104, routing resources 180, logic slices 300, logic slice blocks 700 or 900, and/or other physical components of PLD 100), and thus determine a layout for the PLD 100. In some embodiments, the placement may be performed on one or more previously-stored NCD files, with the placement results stored as another physical design file.

In operation 1250, system 130 performs a routing process to route connections (e.g., using routing resources 180 or input switch stages 210, 310 or those switch stages shown in FIGS. 7 and 9) among the components of PLD 100 based on the placement layout determined in operation 1240 to realize the physical interconnections among the placed components. In some embodiments, the routing may be performed on one or more previously-stored NCD files, with the routing results stored as another physical design file.

In various embodiments, routing the connections in operation 1250 may further involve performing an optimization process on the user design to reduce propagation delays, consumption of PLD resources and/or routing resources, and/or otherwise optimize the performance of the PLD when configured to implement the user design. The optimization process may in some embodiments be performed on a physical design file representing the converted/translated user design, and the optimization process may represent the optimized user design in the physical design file (e.g., to produce an optimized physical design file).

In some embodiments, the optimization process may include optimizing certain instances of a logic function operation, a ripple arithmetic operation, and/or an extended logic function operation which, when a PLD is configured to implement the user design, would occupy a plurality of configurable PLD components (e.g., logic blocks 104, 200, and/or logic slices 300, and/or logic slice blocks 700 or 900, and/or routing resources 180, and/or input switch stages, such as input switch stage 210 or 310 or input switch stages illustrated in FIG. 7 or 9). For example, the optimization process may include detecting multiple mode or configurable logic blocks implementing logic function operations, ripple arithmetic operations, extended logic function operations, and/or corresponding routing resources in the user design, interchanging operational modes of logic blocks implementing the various operations to reduce the number of PLD components and/or routing resources used to implement the operations and/or to reduce the propagation delay associated with the operations, and/or reprogramming corresponding LUTs and/or mode logic to account for the interchanged operational modes.

In another example, the optimization process may include detecting extended logic function operations and/or corresponding routing resources in the user design, implementing the extended logic operations into multiple mode or convertible logic blocks with single physical logic block outputs, routing or coupling the logic block outputs of a first set of logic blocks to the inputs of a second set of logic blocks to reduce the number of PLD components used to implement the extended logic operations and/or routing resources and/or to reduce the propagation delay associated with the extended logic operations, and/or programming corresponding LUTs and/or mode logic to implement the extended logic function operations with at least the first and second sets of logic blocks.

In another example, the optimization process may include detecting multiple mode or configurable logic blocks implementing logic function operations, ripple arithmetic operations, extended logic function operations, and/or corresponding routing resources in the user design, interchanging operational modes of logic blocks Implementing the various operations to provide a programmable register along a signal path within the PLD to reduce propagation delay associated with the signal path, and reprogramming corresponding LUTs, mode logic, and/or other logic block control bits/registers to account for the interchanged operational modes and/or to program the programmable register to store or latch a signal on the signal path.

Changes in the routing may be propagated back to prior operations, such as synthesis, mapping, and/or placement, to further optimize various aspects of the user design.

Thus, following operation 1250, one or more physical design files may be provided which specify the user design after it has been synthesized (e.g., converted and optimized), mapped, placed, and routed (e.g., further optimized) for PLD 100 (e.g., by combining the results of the corresponding previous operations). In operation 1260, system 130 generates configuration data for the synthesized, mapped, placed, and routed user design. In operation 1270, system 130 configures PLD 100 with the configuration data by, for example, loading a configuration data bitstream into PLD 100 over connection 140.

Any aspects of the present disclosure may be combined with any aspects of the disclosures of U.S. patent application Ser. No. 18/641,172 filed Apr. 19, 2024 entitled “HIGH-SPEED MULTI-MODE LOGIC BLOCK WITH COMBINED OUTPUTS FOR PROGRAMMABLE LOGIC DEVICES” and U.S. Provisional Patent Application No. 63/653,030 filed May 29, 2024 entitled “CONFIGURABLE LOGIC SLICE SYSTEMS AND METHODS FOR PROGRAMMABLE LOGIC DEVICES,” all of which are incorporated herein by reference in their entirety.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

What is claimed is:

1. A programmable logic device (PLD) comprising:
a logic slice comprising:
a first lookup table (LUT) configured to generate a first output;
an input switch stage configured to receive the first output and selectively generate a first signal;
a second LUT configured to receive the first signal and to generate a second output; and
a two-to-one multiplexer configured to receive the first output and the second output and selectively produce an output of the logic slice.

2. The PLD of claim 1, wherein the input switch stage is configured to receive at least one additional input signal and comprises a first multiplexer configured to receive the first output and a first input signal from the at least one additional input signal, and wherein selectively generating the first signal comprises the first multiplexer selecting from among the first output and the first input signal.

3. The PLD of claim 2, wherein the at least one additional input signal comprises at least five input signals, wherein the first LUT is a first four-input LUT (4LUT), wherein the second LUT is a second 4LUT, and wherein the input switch stage is further configured to:
route four of the at least five input signals to the first 4LUT and selectively route the remaining signals of the at least five input signals to the second 4LUT or the two-to-one multiplexer.

4. The PLD of claim 3, wherein the logic slice is selectively configurable as two independent 4LUTs or as an S44 logic configuration.

5. The PLD of claim 3, wherein the first signal is received by the second 4LUT at the fastest input to the second 4LUT.

6. The PLD of claim 1, further comprising a second logic slice, wherein the second logic slice comprises:
a third LUT configured to generate a third output;
a second input switch stage comprising:
a first multiplexer configured to receive the third output and to selectively generate a second signal; and
a second multiplexer configured to receive the output of the logic slice and to selectively generate a third signal;
a fourth LUT configured to receive the second signal and to generate a fourth output; and
a second two-to-one multiplexer configured to receive the third output and the fourth output and selectively produce an output of the second logic slice based on the third signal.

7. The PLD of claim 6, wherein the second input switch stage comprises a third multiplexer connected to the fastest input of the third LUT, and wherein the output of the logic slice is provided as an input to the third multiplexer.

8. The PLD of claim 2, wherein the first LUT is a first four-input LUT (4LUT), wherein the second LUT is a second 4LUT, and wherein the at least one additional input signal is selectively routed to other parts of the input switch stage for selectively multiplexing the at least one additional input into other inputs of the second LUT when the first output is selected by the second multiplexer.

9. A method of operating the PLD of claim 1, comprising:
generating, by the first LUT, the first output;
receiving, by an input switch stage, the first output;
selectively generating, by the input switch stage, the first signal;
receiving, by a second LUT, the first signal;
generating by the second LUT, the second output;
selectively producing, by the two-to-one multiplexer, the output of the logic slice from the first output and the second output.

10. A method of programming the PLD of claim 1, the method comprising:
generating configuration data to configure physical components of the PLD in accordance with a synthesized design; and
programming the PLD with the configuration data.

11. A method of operating a programmable logic device (PLD) comprising a logic slice, the method comprising:
operating the logic slice comprising:
generating, by a first lookup table (LUT), a first output;
receiving, by an input switch stage, the first output;
selectively generating, by the input switch stage, a first signal;
receiving, by a second LUT, the first signal;
generating, by the second LUT, a second output; and
selectively producing, by a two-to-one multiplexer, an output of the logic slice from the first output and the second output.

12. The method of claim 11, wherein the input switch stage comprises a first multiplexer, wherein the receiving the first output comprises receiving, by the first multiplexer, the first output, wherein the operating the logic slice further comprises:
receiving, by the first multiplexer, a first input signal from at least one additional input signal, and wherein the selectively generating comprises selecting, by the first multiplexer, from among the first output and the first input signal.

13. The method of claim 12, wherein the at least one additional input signal comprises at least five input signals, wherein the first LUT is a first four-input LUT (4LUT), wherein the second LUT is a second 4LUT, wherein operating the logic slice further comprises:
routing, by the input switch stage, four of the at least five input signals to the first 4LUT; and
selectively routing, by the input switch stage, the remaining signals of the at least five input signals to the second 4LUT or the two-to-one multiplexer.

14. The method of claim 13, wherein the logic slice is selectively configurable as two independent 4LUTs or as an S44 logic configuration.

15. The method of claim 13, wherein the first signal is received by the second 4LUT at the fastest input to the second 4LUT.

16. The method of claim 11, further comprising:
operating a second logic slice comprising:
generating, by a third LUT, a third output;
receiving, by a first multiplexer in a second input switch stage, the third output;
receiving, by a second multiplexer in the second input switch stage, the output of the logic slice;
selectively generating, by the first multiplexer, a second signal;
selectively generating, by the second multiplexer, a third signal;
receiving, by a fourth LUT, the second signal;
generating, by the fourth LUT, a fourth output; and
selectively producing an output of the second logic slice from the third output and the fourth output based on the third signal.

17. The method of claim 16, wherein the second input switch stage comprises a third multiplexer connected to the fastest input of the third LUT, and wherein the output of the logic slice is provided as an input to the third multiplexer.

18. The method of claim 12, wherein first LUT is a first four-input LUT (4LUT), wherein the second LUT is a second 4LUT, and wherein the at least one additional input signal is selectively routed to other parts of the input switch stage for selectively multiplexing the at least one additional input into other inputs of the second LUT when the first output is selected by the second multiplexer.

19. A method of programming a programmable logic device (PLD), the PLD comprising:
a plurality of logic slices, wherein each of the plurality of logic slices comprises:
a first lookup table (LUT) configured to generate a first output;
an input switch stage configured to receive the first output and selectively generate a first signal;
a second LUT configured to receive the first signal and to generate a second output; and
a two-to-one multiplexer configured to receive the first output and the second output and selectively produce an output of the logic slice, the method comprising:
generating configuration data to configure physical components of the PLD in accordance with a synthesized design comprising, for each logic slice, an operating mode depending on the configuration of the input switch stage; and
programming the PLD with the configuration data.

20. The method of claim 19, wherein the input switch stage of each logic slice comprises a plurality of multiplexers, and wherein the configuration data establishes signal selection for each of the plurality of multiplexers for each input switch stage.
